(19) United States
(12) Patent Application Publication
(10) Pub. No.: US 2025/0321363 A1
(43) Pub. Date: Oct. 16, 2025

(54) DISPLAY DEVICE, ELECTRONIC DEVICE AND METHOD OF MANUFACTURING THE DISPLAY DEVICE

(71) Applicant: Samsung Display Co., LTD., Yongin-si (KR)

(72) Inventor: SOOJIN SUNG, Yongin-si (KR)

(21) Appl. No.: 19/051,918

(22) Filed: Feb. 12, 2025

(30) Foreign Application Priority Data
Apr. 11, 2024 (KR) 10-2024-0048780

(51) Int. Cl. G02B 1/14

(52) U.S. Cl. CPC G02B 1/14

(57) ABSTRACT

A display device includes a display panel and a window disposed on the display panel. The window includes a base layer disposed on the display panel, a hard coating layer disposed on the base layer, a high refractive layer disposed on the hard coating layer and including a first base resin, and a low refractive layer disposed on the high refractive layer and consisting of a first inorganic particle.

This application claims priority to Korean Patent Application No. 10-2024-0048780, filed on Apr. 11, 2024, and all the benefits accruing therefrom under 35 U.S.C. § 119, the content of which in its entirety is herein incorporated by reference.

### BACKGROUND

### 1. Field

The present disclosure relates to a display device and a method of manufacturing the display device. More particularly, the present disclosure relates to a display device with improved hardness and excellent folding characteristics and a method of manufacturing the display device.

### 2. Description of Related Art

Various types of electronic devices are being used to provide image information, and electronic devices including a flexible display panel that is foldable or bendable are being developed. Different from a rigid display device, a flexible display device is able to be folded, rolled, or bent. Since the shape of the flexible display device may be changed in various ways, the flexible display device may be carried regardless of the size of its screen displaying images.

A flexible display device may include a window that protects the display panel without causing disruption to the folding or bending operation, and accordingly, developing a window having excellent folding characteristics without deteriorating mechanical properties of such a flexible display device may be desired.

### SUMMARY

The present disclosure provides a display device including a window with improved hardness and excellent folding characteristics to improve its reliability.

The present disclosure provides a method of manufacturing the display device.

Embodiments of the present disclosure provide a display device including a display panel and a window disposed on the display panel. The window includes a base layer disposed on the display panel, a hard coating layer disposed on the base layer, a high refractive layer disposed on the hard coating layer and including a first base resin, and a low refractive layer disposed on the high refractive layer and consisting of a first inorganic particle.

The high refractive layer has a thickness ranging from about 20 nm to about 100 nm.

The high refractive layer further includes a second inorganic particle dispersed in the first base resin.

The high refractive layer is disposed directly on the hard coating layer, and the low refractive layer is disposed directly on the high refractive layer.

The high refractive layer has a refractive index ranging from 1.7 about to about 2.0, and the low refractive layer has a refractive index ranging from about 1.2 to about 1.5.

The first inorganic particle includes silicon oxide (SiOₓ).

The high refractive layer further includes at least one of tin oxide (SnOₓ), titanium oxide (TiOₓ), and zirconium oxide (ZrOₓ).

The first base resin includes a (meta)acrylate-based resin.

The window further includes a functional layer disposed on the low refractive layer and including a fluorine-containing compound.

Each of the high refractive layer and the low refractive layer is provided in plurality, and the high refractive layers are alternately arranged with the low refractive layers in a thickness direction.

The window further includes an adhesive layer disposed between the high refractive layer and the low refractive layer and including a coupling agent.

The window further includes a buffer layer disposed between the high refractive layer and the low refractive layer and including a second base resin.

The display device includes at least one folding area foldable with respect to a folding axis extending in a direction.

Embodiments of the present disclosure provide a display device including a display panel including a folding area foldable with respect to a folding axis extending in a direction and a non-folding area adjacent to the folding area and a window disposed on the display panel. The window includes a base layer disposed on the display panel, a high refractive layer disposed on the base layer and including a first base resin, and a low refractive layer disposed on the high refractive layer and consisting of a first inorganic particle.

The high refractive layer has a thickness equal to or smaller than about 100 nm.

Embodiments of the present disclosure provide a method of manufacturing a display device. The method includes preparing a display panel and providing a window on the display panel. The providing of the window includes preparing a base layer, forming a high refractive layer including a first base resin on the base layer, and forming a low refractive layer including a first inorganic particle on the high refractive layer using a physical deposition. The low refractive layer has a thickness equal to or smaller than about 100 nm.

The low refractive layer consists of the first inorganic particle.

The forming of the low refractive layer is performed by an electron beam deposition method or a sputtering method.

The method further includes forming a hard coating layer on a surface of the base layer before the forming of the high refractive layer on the base layer.

The forming of the high refractive layer includes coating a resin composition including the first base resin and a second inorganic particle distributed in the first base resin on the base layer and drying or curing the resin composition.

According to the above, the window has improved surface hardness and excellent folding characteristics, and thus, the reliability of the display device is improved.

According to the method of manufacturing the display device, both a wet film manufacturing process and a dry film manufacturing process are applied in the providing of the window, and thus, the display device has excellent mechanical property and folding characteristics.

### BRIEF DESCRIPTION OF THE DRAWINGS

The above and other advantages of the present disclosure will become readily apparent by reference to the following detailed description when considered in conjunction with the accompanying drawings wherein:

FIG. 1A is a perspective view of a display device in an unfolded state according to an embodiment of the present disclosure;

FIG. 1B is a perspective view of a display device being inwardly folded according to an embodiment of the present disclosure;

FIG. 1C is a perspective view of a display device being outwardly folded according to an embodiment of the present disclosure;

FIG. 2A is a perspective view of a display device in an unfolded state according to an embodiment of the present disclosure;

FIG. 2B is a perspective view of the display device of FIG. 2A, which is being inwardly folded, according to an embodiment of the present disclosure;

FIG. 3 is an exploded perspective view of a display device according to an embodiment of the present disclosure;

FIG. 4 is a cross-sectional view of a display device according to an embodiment of the present disclosure;

FIGS. 5A to 5D are cross-sectional views of a window according to an embodiment of the present disclosure;

FIG. 6 is a block diagram of an electronic device according to an embodiment.

FIG. 7 illustrates schematic views of electronic devices according to various embodiments.

FIG. 8A is a flowchart illustrating a method of manufacturing a display device according to an embodiment of the present disclosure;

FIG. 8B is a flowchart illustrating a process of providing a window according to an embodiment of the present disclosure; and

FIGS. 9A to 9F are cross-sectional views illustrating some processes of a method of manufacturing a display device according to an embodiment of the present disclosure.

### DETAILED DESCRIPTION

Hereinafter, embodiments of the present disclosure will be described with reference to accompanying drawings.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, and the like may be used herein to describe various elements, these elements should not be limited by these terms. These terms are used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as illustrated in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

In the present disclosure, when an element is referred to as being “directly connected” to another element, there are no intervening elements present between a layer, film region, or substrate and another layer, film, region, or substrate. For example, the term “directly connected” may mean that two layers or two members are disposed without employing additional adhesive therebetween.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a window and a display device including the window of the present disclosure will be described with reference to accompanying drawings.

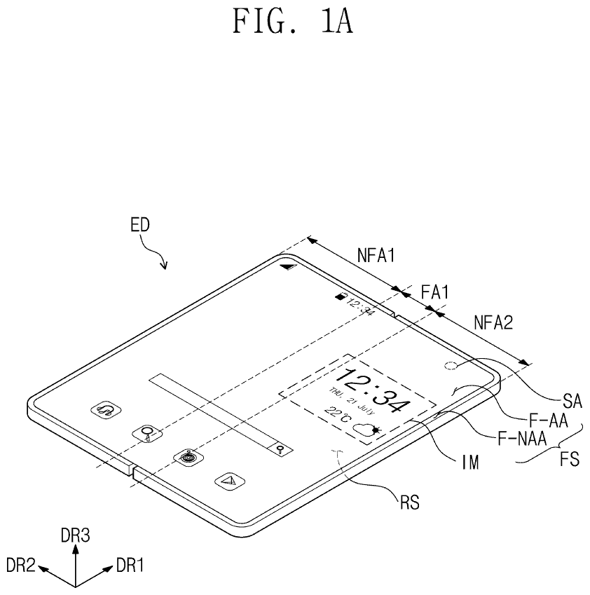

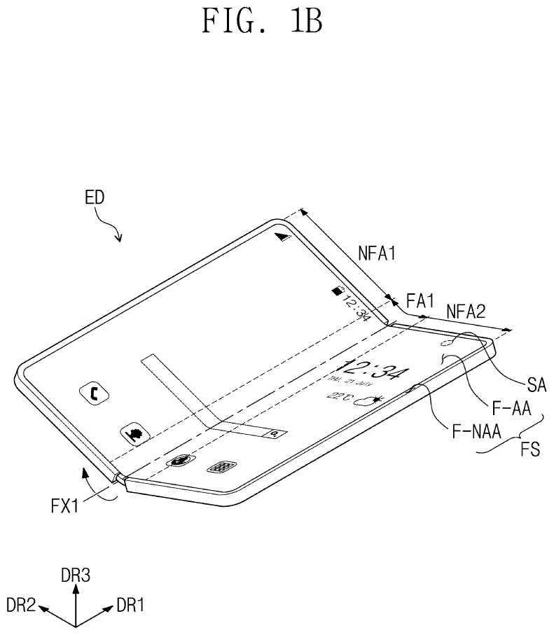

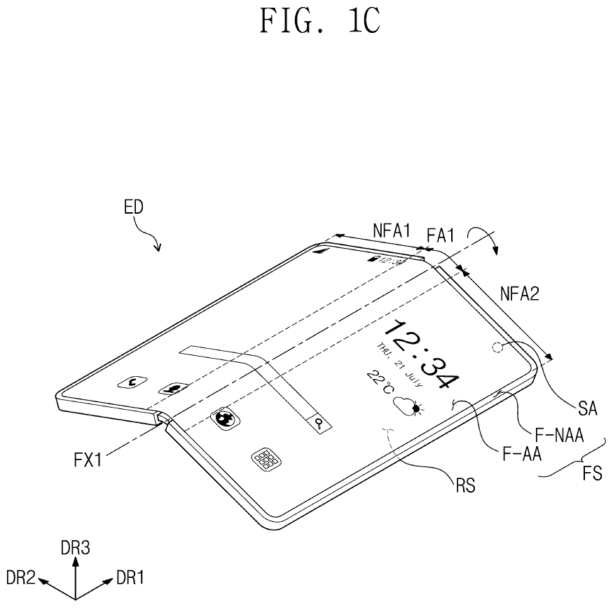

FIG. 1A is a perspective view of a display device ED in an unfolded state according to an embodiment of the present disclosure. FIG. 1B is a perspective view of the display device ED of FIG. 1A, which is being inwardly folded, according to an embodiment of the present disclosure. FIG. 1C is a perspective view of the display device ED of FIG. 1A, which is being outwardly folded, according to an embodiment of the present disclosure.

The display device ED may be activated in response to electrical signals. As an example, the display device ED may be a mobile phone, a tablet computer, a car navigation unit, a game unit, or a wearable device, however, embodiments of the present disclosure are not limited thereto. In FIGS. 1A to 1C, the mobile phone will be described as a representative example of the display device ED.

FIGS. 1A to 1C show a foldable display device that is transformed into a folded form as a representative example of the display device ED, but the present disclosure should not be limited thereto or thereby. According to an embodiment, the display device ED may be a flexible display device that is curved or rolled.

In some embodiments, FIG. 1A and the following drawings show first, second, and third directions DR1, DR2, and DR3, and directions indicated by the first, second, and third directions DR1, DR2, and DR3 may be relative to each other and may be changed to other directions.

Referring to FIGS. 1A to 1C, the display device ED may include a display surface FS defined by the first direction DR1 and the second direction DR2 intersecting the first direction DR1. The display device ED may provide an image IM to a user through the display surface FS. The display device ED may display the image IM through the display surface FS, which is substantially parallel to each of the first direction DR1 and the second direction DR2, toward the third direction DR3. In the present disclosure, front (or upper) and rear (or lower) surfaces of each component of the display device ED may be defined with respect to a direction in which the image IM is displayed.

The display device ED may sense an external input applied thereto from an outside of the display device ED. The external input may include various forms of inputs provided from the outside of the display device ED. For example, the external inputs may include a proximity input (e.g., hovering) applied when approaching close to or adjacent to the display device ED at a predetermined distance as well as a touch input by a user's body (e.g., user's hand). In some aspects, the external inputs may be provided in the form of force, pressure, temperature, light, or the like.

The display surface FS of the display device ED may include an active area F-AA and the peripheral area F-NAA. The active area F-AA may be activated in response to the electrical signals. The display device ED may display the image IM through the active area F-AA. In some aspects, various external inputs may be sensed through the active area F-AA. The peripheral area F-NAA may be defined adjacent to the active area F-AA. The peripheral area F-NAA may have a predetermined color. The peripheral area F-NAA may surround the active area F-AA. Accordingly, the active area F-AA may have a shape that is substantially defined by the peripheral area F-NAA. However, embodiments of the present disclosure are not limited thereto. The peripheral area F-NAA may be defined adjacent to a single side of the active area F-AA or may be omitted. According to an embodiment, the display device ED may include the active area of various shapes, and embodiments of the present disclosure are not limited thereto.

The active area F-AA may include a sensing area SA. Various electronic modules may be disposed in the sensing area SA. For example, the electronic module may include at least one of a camera module, a speaker, an optical sensor, and a thermal sensor. The sensing area SA may sense an external subject through the display surface FS or may provide a sound signal, such as a voice input, to the outside through the display surface FS. In some aspects, the electronic module may include a plurality of components, however, embodiments of the electronic module are not limited thereto.

The sensing area SA may be surrounded by the active area F-AA and the peripheral area F-NAA, however, embodiments of the present disclosure are not limited thereto. The sensing area SA may be defined in the active area F-AA, but the sensing area SA is not particularly limited thereto. FIG. 1A illustrates one sensing area SA as a representative example, however, the number of sensing areas SA should not be limited thereto or thereby.

The sensing area SA may be a part of the active area F-AA. Accordingly, the display device ED may also display the image IM through the sensing area SA. In an example in which the electronic modules disposed in the sensing area SA are deactivated, a video or a still image may be displayed through the sensing area SA that serves as a display surface

A rear surface RS of the display device ED may be opposite to the display surface FS. According to an embodiment, the rear surface RS may correspond to an external surface of the display device ED, and the video or the still image may not be displayed through the rear surface RS. However, the present disclosure should not be limited thereto or thereby, and the rear surface RS may serve as a display surface through which the video or the still image is displayed. In some aspects, according to an embodiment, the display device ED may further include a sensing area defined in the rear surface RS. Various electronic modules, such as a camera, a speaker, an optical sensor, and the like, may also be disposed in the sensing area defined in the rear surface RS.

The display device ED may include a folding area FA1 and non-folding areas NFA1 and NFA2. The display device ED may include a plurality of non-folding areas NFA1 and NFA2. The display device ED may include a first non-folding area NFA1 and a second non-folding area NFA2 spaced apart from the first non-folding area NFA1, with the folding area FA1 interposed between the first non-folding area NFA1 and the second non-folding area NFA2. In some embodiments, FIGS. 1A to 1C show the display device ED including one folding area FA1 as a representative example, however, the display device ED should not be limited thereto or thereby. According to an embodiment, the display device ED may include a plurality of folding areas defined therein. According to an embodiment, the display device ED may be folded about a plurality of folding axes such that a portion of the display surface FS faces another portion of the display surface FS, and the number of the folding axes and the number of non-folding areas is not particularly limited.

Referring to FIGS. 1B and 1C, the display device ED may be folded with respect to a first folding axis FX1. The first folding axis FX1 illustrated in FIGS. 1B and 1C may be an imaginary axis extending in the first direction DR1 to be substantially parallel to a direction in which a long side of the display device ED extends. However, the present disclosure should not be limited thereto or thereby, and the extension direction of the first folding axis FX1 should not be limited to the first direction DR1.

The first folding axis FX1 may extend in the first direction DR1 on the display surface FS or may extend in the first direction DR1 on the rear surface RS. Referring to FIG. 1B, the display device ED may be inwardly folded (in-folding) such that the first non-folding area NFA1 faces the second non-folding area NFA2 and the display surface FS is not exposed to the outside. In some aspects, referring to FIG. 1C, the display device ED may be folded about the first folding axis FX1 to be in the outwardly folded (out-folding) state where one area of the rear surface RS, which overlaps the first non-folding area NFA1, faces the other area of the rear surface RS, which overlaps the second non-folding area NFA2.

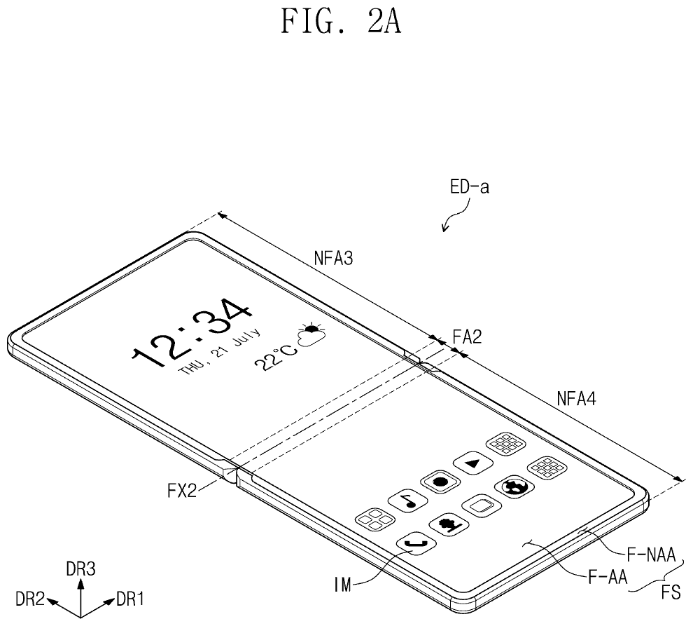

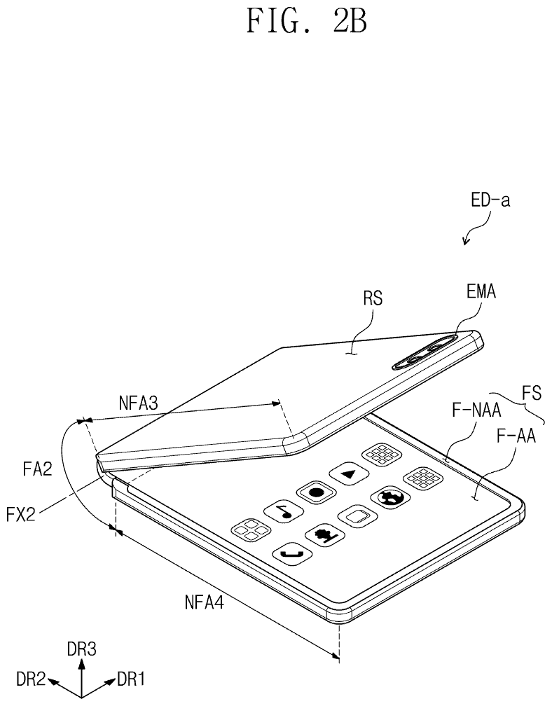

FIG. 2A is a perspective view of a display device ED-a in an unfolded state according to an embodiment of the present disclosure, and FIG. 2B is a perspective view of the display device ED-a of FIG. 2A, which is being inwardly folded according to an embodiment of the present disclosure.

The display device ED-a may be folded with respect to a second folding axis FX2 extending in a direction substantially parallel to the first direction DR1. In FIG. 2B, the second folding axis FX2 extends substantially parallel to a direction in which a short side of the display device ED-a extends, however, embodiments of the present disclosure are not limited thereto.

According to an embodiment, the display device ED-a may include at least one folding area FA2 and non-folding areas NFA3 and NFA4 defined adjacent to the folding area FA2. The non-folding areas NFA3 and NFA4 may be spaced apart from each other with the folding area FA2 interposed between the non-folding areas NFA3 and NFA4.

The folding area FA2 may have a predetermined curvature and a radius of curvature. According to an embodiment, the display device ED-a may be inwardly folded (in-folding) such that a first non-folding area NFA3 faces a second non-folding area NFA4 and a first display surface FS is not exposed to the outside.

In some aspects, different from the display device ED-a illustrated in FIGS. 2A and 2B, the display device ED-a may be outwardly folded (out-folding) such that the first display surface FS is exposed to the outside. In some embodiments, the first display surface FS may be viewed by the user in the unfolded state of the display device ED-a, and a second display surface RS may be viewed by the user in the inwardly folded (in-folding) state. The second display surface RS may include an electronic module area EMA in which an electronic module including various components is disposed.

According to an embodiment, the display device ED-a may include the second display surface RS, and the second display surface RS may be defined as a surface opposite to at least a portion of the first display surface FS. In some embodiments, according to an embodiment, the image may be provided through the second display surface RS.

The display devices ED and ED-a may be configured to repeat the unfolding operation and the in-folding operation or to repeat the unfolding operation and the out-folding operation, however, the present disclosure should not be limited thereto or thereby. According to an embodiment, the display devices ED and ED-a may be selectively operated in any one of the unfolding operation, the in-folding operation, and the out-folding operation.

FIGS. 1A to 2B show a foldable display device that is transformed into a folded form as a representative example of the display devices ED and ED-a, but the present disclosure should not be limited thereto or thereby. According to an embodiment, the display devices ED and ED-a may be a flexible display device that is curved or rolled.

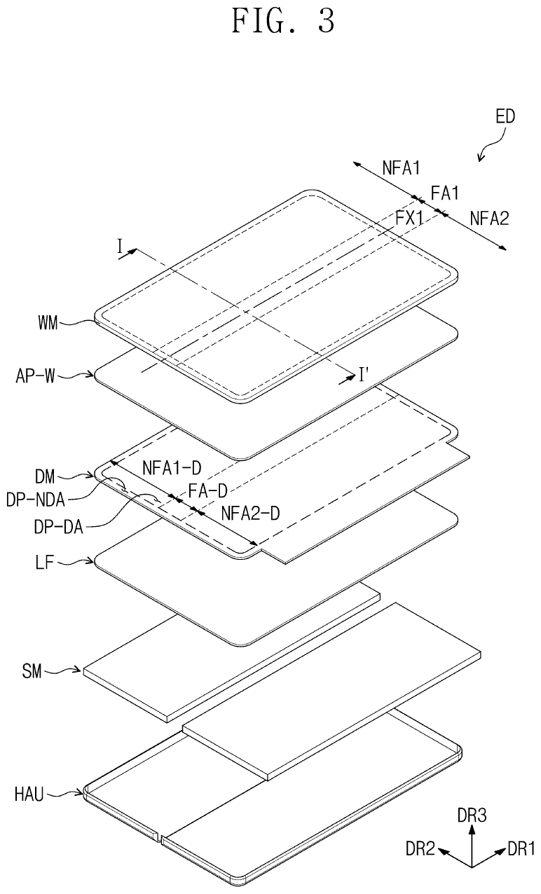

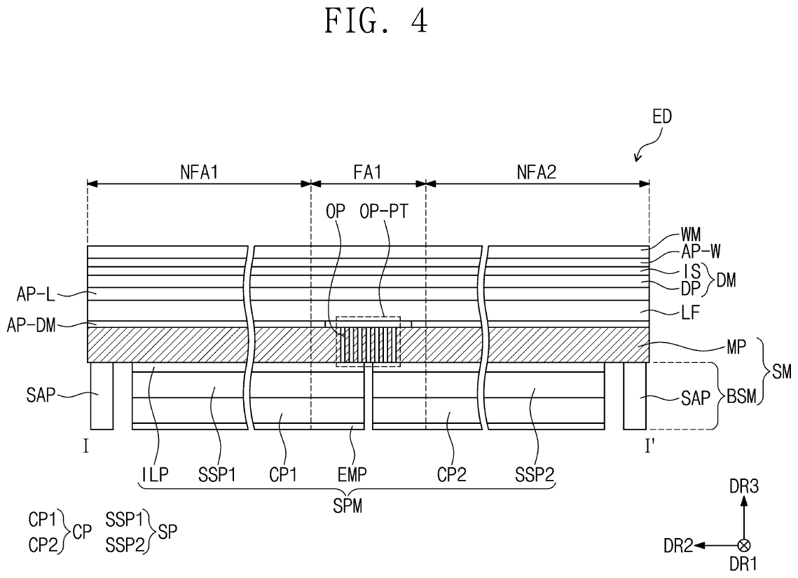

FIG. 3 is an exploded perspective view of the display device ED according to an embodiment of the present disclosure, and FIG. 4 is a cross-sectional view of the display device ED according to an embodiment of the present disclosure. FIG. 3 is an exploded perspective view of the display device ED of FIG. 1A, and FIG. 4 is a cross-sectional view taken along a line I-I′ of FIG. 3.

Referring to FIGS. 3 and 4, the display device ED may include a display module DM and a window WM disposed on the display module DM. In some aspects, the display device ED may include a support module SM disposed under the display module DM. In FIGS. 3 and 4, the display device ED illustrated in FIGS. 1A to 1C will be described as a representative example, however, descriptions described herein may be applied to the display device ED-a illustrated in FIGS. 2A and 2B.

The window WM may entirely cover an upper surface of the display module DM. The window WM may have a shape corresponding to a shape of the display module DM. In some aspects, the display device ED may include a housing HAU to accommodate the display module DM and the support module SM. Although not illustrated in figures, the housing HAU may be coupled with the window WM. Although not illustrated in figures, the housing HAU may further include a hinge structure which supports relatively easy folding or bending of the display device ED.

The display module DM may display the image in response to electrical signals and may transmit/receive information about the external input. A display surface of the display module DM may include a display area DP-DA and a non-display area DP-NDA. The display area DP-DA may be defined as an area through which the image provided from the display module DM transmits.

The non-display area DP-NDA may be defined adjacent to the display area DP-DA. As an example, the non-display area DP-NDA may surround the display area DP-DA. However, embodiments of the present disclosure are not limited to the example, and the non-display area DP-NDA may be defined in various shapes. According to an embodiment, the display area DP-DA of the display module DM may correspond to at least a portion of the active area F-AA (refer to FIG. 1A).

The display module DM may include a folding display portion FA-D and non-folding display portions NFA1-D and NFA2-D. The folding display portion FA-D may correspond to the folding area FA1 of the display device ED, and the non-folding display portions NFA1-D and NFA2-D may correspond to the non-folding areas NFA1 and NFA2 of the display device ED.

The window WM may be disposed on the display module DM. The window WM may include an optically transparent insulating material. The window WM may protect a display panel DP and a sensor layer IS. That is, the window WM may be a cover window that covers an upper portion of the display module DM.

The image IM (refer to FIG. 1A) generated from the display panel DP may be provided to the user after passing through the window WM. The window WM may provide a touch surface of the display device ED. In the display device ED including the folding area FA1, the window WM may be a flexible window that is foldable.

The window WM may provide the display surface and the touch surface and may have excellent optical characteristics. The window WM may have a high transmittance of more than about 90% in a visible light range of about 380 nm to about 780 nm.

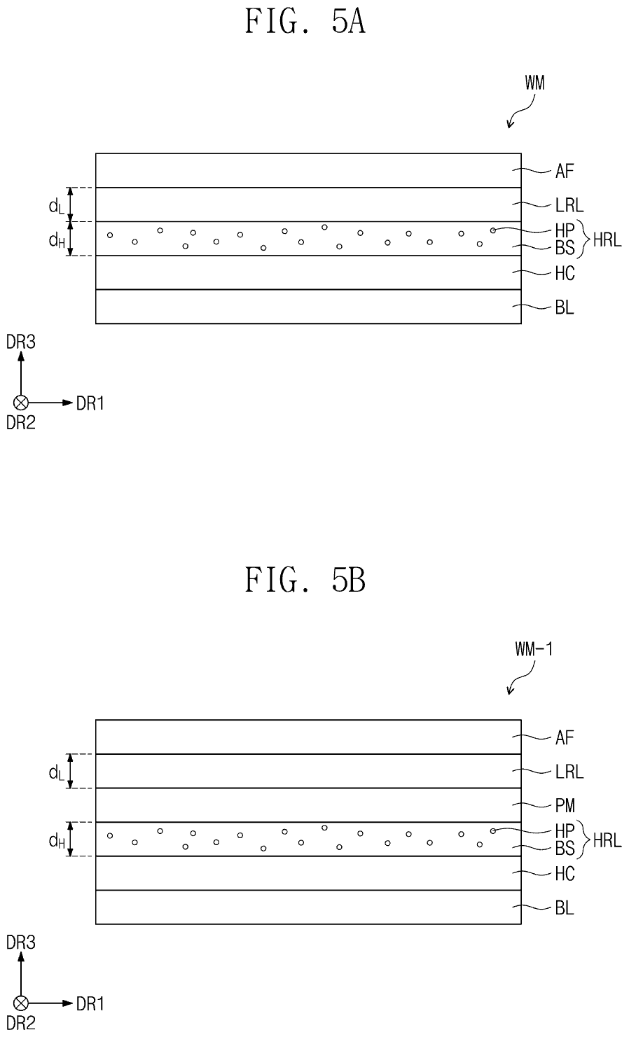

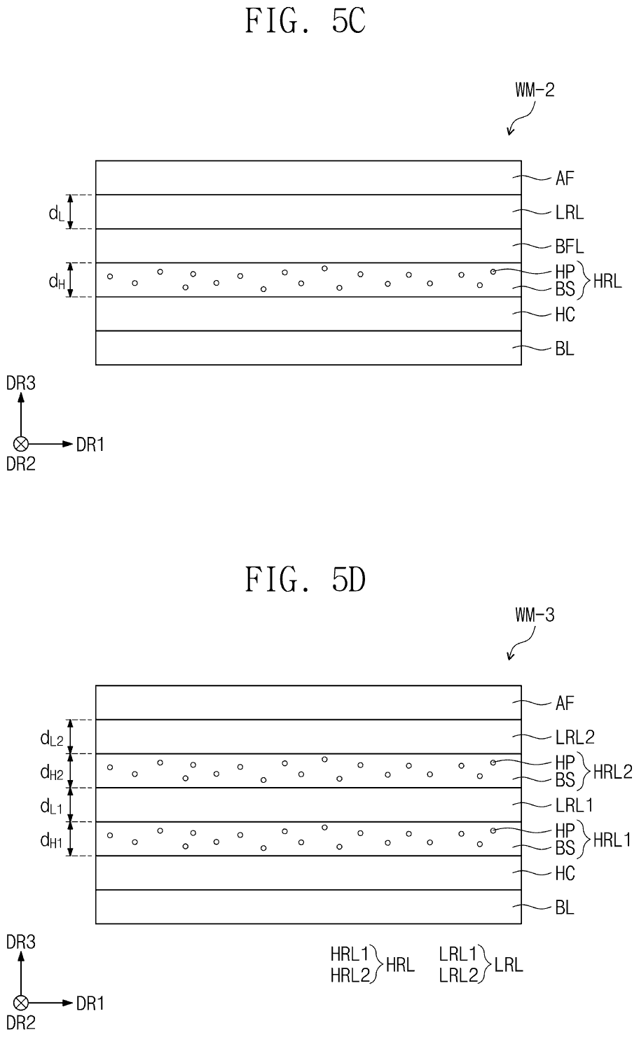

The window WM may include a base layer BL (refer to FIG. 5A), a high refractive layer HRL (refer to FIG. 5A) disposed on the base layer BL (refer to FIG. 5A), and a low refractive layer LRL (refer to FIG. 5A) disposed on the high refractive layer HRL (refer to FIG. 5A). The window WM will be described in detail later.

The display module DM may include the display panel DP and the sensor layer IS disposed on the display panel DP. Although not illustrated in figures, the display module DM may further include an optical layer (not illustrated) disposed on the sensor layer IS. The optical layer (not illustrated) may reduce a reflection of an external light. As an example, the optical layer (not illustrated) may include a polarizing layer or a color filter layer.

The display panel DP may have a configuration that substantially generates the image. As an example, the display panel DP may be an organic light emitting display panel, an inorganic light emitting display panel, a quantum dot display panel, a micro-LED display panel, a nano-LED display panel, or a liquid crystal display panel. The display panel DP may be referred to as a display layer.

The sensor layer IS may be disposed on the display panel DP. The sensor layer IS may sense an external input applied thereto from the outside. The external input may be a user's input. The user's input may include various forms of external input, such as, for example, parts of the user's body, light, heat, pen, or pressure.

The sensor layer IS of the display module DM may be formed on the display panel DP through successive processes. In this case, the sensor layer IS may be expressed as being disposed directly on the display panel DP. The expression “the sensor layer IS is disposed directly on the display panel DP” may mean that no intervening elements are present between the sensor layer IS and the display panel DP. That is, a separate adhesive member may not be disposed between the sensor layer IS and the display panel DP. According to an embodiment, the sensor layer IS may be coupled with the display panel DP by an adhesive member. The adhesive member may include a conventional adhesive.

A window adhesive layer AP-W may be disposed between the window WM and the display module DM. The window adhesive layer AP-W may be an optically clear adhesive film (OCA) or an optically clear adhesive resin layer (OCR).

The display device ED may include a lower film LF disposed under the display module DM. The lower film LF disposed under the display module DM may protect a lower portion of the display panel DP. The display device ED may include a lower adhesive layer AP-L (refer to FIG. 4) to attach the lower film LF to the display module DM.

The lower film LF may be a polymer film. As an example, the lower film LF may include polyethylene terephthalate (PET) film or polyimide (PI) film. The lower film LF may prevent scratches from occurring on a rear surface of the display panel DP during a manufacturing process of the display panel DP. In some aspects, the lower film LF may protect the display panel DP from a pressure applied to the display panel DP from the outside to prevent the display panel DP from being deformed. The lower film LF may have a single-layer structure of a single film layer or a multi-layer structure of a plurality of film layers stacked one another.

The lower adhesive layer AP-L may be disposed between the display panel DP and the lower film LF. The lower adhesive layer AP-L may include an optically clear adhesive (OCA) film or an optically clear adhesive resin (OCR) layer, however, the present disclosure should not be limited thereto or thereby. The lower adhesive layer AP-L may include an acrylic-based adhesive or a silicone-based adhesive. In some aspects, according to an embodiment, the lower adhesive layer AP-L may be omitted.

The display device ED may include the support module SM disposed under the display module DM. The support module SM may include a support plate MP and a lower support member BSM.

The support plate MP may be disposed under the display module DM. The support plate MP may be disposed under the lower film LF. According to an embodiment, the support plate MP may include a metal material or a polymer material. As an example, the support plate MP may include stainless steel, aluminum, or an alloy thereof. In some aspects, according to an embodiment, the support plate MP may be formed of a carbon fiber reinforced plastic (CFRP), however, the present disclosure should not be limited thereto or thereby. The support plate MP may include a non-metallic material, a plastic material, a glass fiber reinforced plastic (GFRP), or a glass material.

The support plate MP may be provided with a plurality of openings OP defined therethrough. The support plate MP may include an opening pattern OP-PT through which the openings OP are defined. The opening pattern OP-PT may correspond to the folding area FA1.

The lower support member BSM may include a support member SPM and a filling portion SAP. The support member SPM may overlap most of the portion of the display module DM. The filling portion SAP may be disposed outside the support member SPM and may overlap an outer portion of the display module DM.

The lower support member BSM may include at least one of a support layer SP, a cushion layer CP, a shielding layer EMP, and an interlayer adhesive layer ILP. In some embodiments, a configuration of the lower support member BSM should not be limited to that illustrated in FIG. 4, and the configuration of the lower support member BSM may be determined depending on a size or shape of the display device ED or operation characteristics of the display device ED. As an example, one or more of the support layer SP, the cushion layer CP, the shielding layer EMP, and the interlayer adhesive layer ILP may be omitted, a stack order of the support layer SP, the cushion layer CP, the shielding layer EMP, and the interlayer adhesive layer ILP may be changed from the implementation described with reference to FIG. 4, or other components may be further added. As an example, the lower support member BSM may further include a digitizer.

The support layer SP may include a metal material or a polymer material. The support layer SP may be disposed under the support plate MP. As an example, the support layer SP may be a thin metal substrate.

The support layer SP may include a first sub-support layer SSP1 and a second sub-support layer SSP2 spaced apart from the first sub-support layer SSP1 in the second direction DR2. The first sub-support layer SSP1 and the second sub-support layer SSP2 may be spaced apart from each other in a portion corresponding to the folding axis FX1. As the support layer SP includes the first sub-support layer SSP1 and the second sub-support layer SSP2 spaced apart from the first sub-support layer SSP1 in the folding area FA1, the folding or bending characteristics of the display device ED may be improved.

The cushion layer CP may be disposed under the support layer SP. The cushion layer CP may prevent the support plate MP from being pressed and plastic-deformed by external impact and force. The cushion layer CP may improve an impact resistance of the display device ED. The cushion layer CP may include a sponge, a foam, or an elastomer such as, for example, a urethane resin. In some aspects, the cushion layer CP may include at least one of an acrylic-based polymer, a urethane-based polymer, a silicone-based polymer, and an imide-based polymer, however, embodiments of the present disclosure are not limited thereto.

In some aspects, the cushion layer CP may include a first sub-cushion layer CP1 and a second sub-cushion layer CP2 spaced apart from the first sub-cushion layer CP1 in the second direction DR2. The first sub-cushion layer CP1 and the second sub-cushion layer CP2 may be spaced apart from each other in an area corresponding to the folding axis FX1. As the cushion layer CP includes the first sub-cushion layer CP1 and the second sub-cushion layer CP2 spaced apart from the first sub-cushion layer CP1 in the folding area FA1, the folding or bending characteristics of the display device ED may be improved.

The shielding layer EMP may be an electromagnetic shielding layer or a heat dissipation layer. In some aspects, the shielding layer EMP may perform a function of an adhesive layer. The interlayer adhesive layer ILP may attach the support plate MP to the lower support member BSM. The interlayer adhesive layer ILP may be provided in the form of an adhesive resin layer or an adhesive tape. FIG. 4 illustrates a structure in which the interlayer adhesive layer ILP is divided into two portions spaced apart from each other in an area corresponding to the folding area FA1, however, the present disclosure should not be limited thereto or thereby. The interlayer adhesive layer ILP may be provided in the form of a single layer without being divided in the folding area FA1.

The filling portion SAP may be disposed outside the support layer SP and the cushion layer CP. The filling portion SAP may be disposed between the support plate MP and the housing HAU. The filling portion SAP may be filled in a space between the support plate MP and the housing HAU and may fix the support plate MP.

In some aspects, the display device ED may further include a module adhesive layer AP-DM disposed between the lower film LF and the support module SM. The module adhesive layer AP-DM may be an optically clear adhesive film (OCA) or an optically clear adhesive resin layer (OCR). In some embodiments, although not illustrated in figures, an adhesive layer may be further disposed between members included in the support module SM.

The display device ED described with reference to FIGS. 1A to 4 may include the display module DM and the window WM disposed on the display module DM and may include at least one folding area.

In some embodiments, the structure of the display device should not be limited to the above descriptions, the display device may include a plurality of folding areas, or the extension direction of the folding axis should not be limited to the above direction and may be changed in various ways. In some aspects, the display device may be the flexible display device whose at least a portion is bendable or rollable.

FIG. 5A is a cross-sectional view of the window WM according to an embodiment of the present disclosure. The window WM illustrated in FIG. FIG. 5A may be the window WM illustrated in FIGS. 3 and 4. The window WM illustrated in FIG. 5A may be used as a cover window of the display devices ED and ED-a described with reference to FIGS. 1A to 4.

Referring to FIG. 5A, the window WM may include the base layer BL, the high refractive layer HRL disposed on the base layer BL, and the low refractive layer LRL disposed on the high refractive layer HRL. Hereinafter, descriptions on the base layer BL, the high refractive layer HRL, and the low refractive layer LRL included in the window WM, may also be applied to windows WM-1, WM-2, and WM-3 described with reference to FIGS. 5B to 5D.

The base layer BL may be formed of a polymer material. The base layer BL may be a flexible polymer film. The base layer BL of the window WM may be a polymer film layer. The base layer BL may include at least one of polyimide (PI), polyethylene terephthalate (PET), polyamide (PA), polycarbonate (PC), and triacetyl cellulose (TAC), however, the present disclosure should not be limited thereto or thereby. According to an embodiment, materials for the base layer BL may have an optical transparency and a flexibility supportive of the features described herein, and the materials are not particularly limited to the examples described herein. As an example, the window WM may include a polyethylene terephthalate film as its base layer BL. In an example in which the base layer BL of the window WM includes the polyethylene terephthalate film, the base layer BL may have excellent optical properties such as, for example, low haze, high transmittance, and the like.

The base layer BL may have a thickness ranging from about 20 μm to about 100 μm. In an example in which the thickness of the base layer BL is smaller than about 20 μm, the base layer BL may not serve as a support layer for the components disposed thereon, such as, the high refractive layer HRL, and may not protect the display module DM (refer to FIG. 3) disposed thereunder. In some aspects, when the thickness of the base layer BL is greater than about 100 μm, a total thickness of the display device ED (refer to FIG. 3) may increase. In particular, when the display devices ED and ED-a are foldable as illustrated in FIGS. 1A to 2B, the folding characteristics of the display devices ED and ED-a may deteriorate as the thickness of the base layer BL increases.

The window WM may include one base layer BL. The base layer BL of the window WM may be a single polymer film layer, however, the present disclosure should not be limited thereto or thereby. According to an embodiment, the base layer BL of the window WM may have a structure in which multiple polymer films are stacked. In an example in which the base layer BL includes the multiple polymer films, the polymer films may include the same type of polymer materials or the polymer films may respectively be formed of different polymer materials.

The window WM may include the high refractive layer HRL containing a first base resin BS and the low refractive layer LRL consisting of a first inorganic particle. According to the window WM, the high refractive layer HRL may be formed through a wet film manufacturing process, and the low refractive layer LRL may be formed through a dry film manufacturing process.

In the present disclosure, the term of “wet film manufacturing process” refers to a process of manufacturing a film by providing a resin composition containing a base resin and then drying or curing the resin composition. If some aspects, as applicable or appropriate, the resin composition used in the “wet film manufacturing process” may further contain inorganic particles dispersed in the base resin. In some non-limiting examples, the film formed through the “wet film manufacturing process” may contain the base resin in cured or dried form as an included component. In some aspects, the term of “dry film manufacturing process” refers to a process of depositing inorganic particles, which are a material for deposition, on a target substrate through a physical deposition process. The “dry film manufacturing process” may be implemented without a separate base resin, and the film manufactured by the “dry film manufacturing process” may consist of the inorganic particles that are the material for deposition.

The high refractive layer HRL may be disposed above the base layer BL. According to an embodiment, the high refractive layer HRL may be disposed directly on the base layer BL. A lower surface of the high refractive layer HRL may be in contact with an upper surface of the base layer BL. In some embodiments, the base layer BL may include a lower surface that is adjacent to the display module DM (refer to FIG. 3) and the upper surface opposite to its lower surface, and the high refractive layer HRL may be disposed on the upper surface of the base layer BL. The high refractive layer HRL may be spaced apart from the display module DM (refer to FIG. 3), with the base layer BL interposed between the high refractive layer HRL and the display module DM.

The high refractive layer HRL may include the first base resin BS. The first base resin BS may include a (meta) acrylic-based resin, a urethane-based resin, a fluorine-based resin, an epoxy-based resin, a polyester-based resin, a polyamide-based resin, a silicone-based resin, or a combination thereof. The first base resin BS may include the (meta) acrylate-based resin. As the first base resin BS includes the (meta) acrylate-based resin, an impact resistance of the window WM may increase. In some aspects, the high refractive layer HRL may protect the window WM from an external impact or chemical damage. In some embodiments, in the present disclosure, (meth)acrylate may mean acrylate and methacrylate.

The high refractive layer HRL may further include a second inorganic particle HP. The second inorganic particle HP may be distinguished from the first inorganic particle included in the low refractive layer LRL. The second inorganic particle HP may be dispersed in the first base resin BS. In some embodiments, the second inorganic particle HP may have a circular shape as illustrated in FIG. 5A, however, the shape of the second inorganic particle HP is not limited thereto. According to an embodiment, the second inorganic particle HP may have various shapes such as, for example, a cube, an oval, and the like.

The second inorganic particle HP may have a refractive index higher than a refractive index of the first inorganic particle included in the low refractive layer LRL. According to an embodiment, the second inorganic particle HP may include high refractive index inorganic oxide. As an example, the second inorganic particle HP may include at least one of zirconium oxide (ZrOₓ), tin oxide (SnOₓ), and titanium oxide (TiOₓ, 0<x<2).

The high refractive layer HRL including the second inorganic particle HP may have a refractive index within a desired range, and thus the high refractive layer HRL may have sufficient low-reflection characteristics. In some aspects, when the high refractive layer HRL further includes the second inorganic particle HP, a hardness of the window WM may be improved.

When the high refractive layer HRL includes the second inorganic particle HP, a content of the second inorganic particle HP may be about 5 percent by weight or more and about 25 percent by weight or less based on a total weight of the high refractive layer HRL. In an example in which the content of the second inorganic particle HP included in the high refractive layer HRL satisfies the example range regarding content, a mechanical durability of the high refractive layer HRL may be improved, and the window WM may sufficiently exhibit the low-reflection characteristics. In an example in which the content of the second inorganic particle HP is smaller than about 5 percent by weight based on the total weight of the high refractive layer HRL, a refractive index of the high refractive layer HRL may decrease, and thus, a light extraction function of the high refractive layer HRL may be reduced in relation to other members. In some aspects, when the content of the second inorganic particle HP is greater than about 25 percent by weight based on the total weight of the high refractive layer HRL, the content of the second inorganic particle HP in the high refractive layer HRL may relatively increase, and brittleness of the high refractive layer HRL may increase, thereby decreasing flexural strength.

The high refractive layer HRL may have a refractive index greater than a refractive index of the low refractive layer LRL. The refractive index of the high refractive layer HRL may range from about 1.7 to about 2.0. As the refractive index of the high refractive layer HRL satisfies the above refractive index range, a surface reflectance of the window WM may be reduced.

The high refractive layer HRL may have a thickness du ranging from about 20 nm to about 500 nm. In an example in which the thickness of the high refractive layer HRL ranges from about 20 nm to about 500 nm, the window WM may have excellent optical characteristics such as, for example, high transmittance and low reflectance. In some aspects, the window WM including the high refractive layer HRL with the thickness du ranging from about 20 nm to about 500 nm may have excellent impact resistance and improved durability.

The low refractive layer LRL may be disposed on the high refractive layer HRL. The low refractive layer LRL may be disposed directly on the high refractive layer HRL. A lower surface of the low refractive layer LRL may be in contact with the upper surface of the high refractive layer HRL.

The refractive index of the low refractive layer LRL may be adjusted in combination with the refractive index of the base layer BL and the refractive index of the high refractive layer HRL in association with achieving the reflectance of the entire window WM to be equal to or smaller than about 6%. According to embodiments of the present disclosure, the surface reflectance of the window WM may be equal to or smaller than about 6% at a wavelength of about 360 m to about 700 nm. As an example, the surface reflectance of the window WM may be equal to or smaller than about 6% at a wavelength of about 550 nm. In some embodiments, in the present disclosure, the reflectance of the windows WM, WM-1, WM-2, and WM-3 is defined as a ratio of a light reflected to the outside of the windows WM, WM-1, WM-2, and WM-3 to a light incident from the outside into the windows WM, WM-1, WM-2, and WM-3. The light reflected to the outside includes both a regular reflected light, which is incident and then reflected at the same angle as an angle of the incident light, and a diffusely reflected light, which is scattered and reflected in various directions. That is, the reflectance is defined as a specular component included(SCI)-reflectance in the present disclosure.

The refractive index of the low refractive layer LRL may be smaller than the refractive index of the high refractive layer HRL. As an example, the refractive index of the low refractive layer LRL may range from about 1.2 to about 1.5. However, the present disclosure should not be limited thereto or thereby, and the refractive index of the low refractive layer LRL may be adjusted within the range where the window WM maintains the low reflectance characteristics of about 6% or less.

The window WM may have a two-layer structure in which a layer having a relatively high refractive index and a layer having a relatively low refractive index are sequentially stacked in the third direction DR3. Accordingly, the window WM may have improved reflection preventing effect.

According to the window WM, the low refractive layer LRL may consist of the first inorganic particle. The first inorganic particle included in the low refractive layer LRL may be low refractive index inorganic oxide. As an example, the first inorganic particle included in the low refractive layer LRL may be silicon oxide (SiOₓ, 0<x<2).

The low refractive layer LRL may have a thickness d_{L} ranging from about 20 nm to about 100 nm. Preferably, the thickness du of the low refractive layer LRL may range from about 50 nm to about 100 nm. In an example in which the thickness of the low refractive layer LRL ranges from about 20 nm to about 100 nm, the window WM may have excellent optical characteristics such as, for example, high transmittance and low reflectance. In some aspects, the window WM including the low refractive layer LRL with the thickness d_{L} ranging from about 20 nm to about 100 nm may have excellent impact resistance and improved durability.

The low refractive layer LRL may not include a base resin. As an example, the low refractive layer LRL may not include an organic binder such as, for example, a (meta) acrylate resin. Since the low refractive layer LRL does not include the base resin, a surface hardness of the low refractive layer LRL may be secured, and thus, the impact resistance of the window WM against the external impact may be improved.

The low refractive layer LRL that consists of the first inorganic particle may improve the surface hardness of the window WM. Since the low refractive layer LRL consists of the first inorganic particle, the surface hardness of the low refractive layer LRL is high, and as a result, defects such as, for example, dents, scratches, and the like, caused by external objects may be prevented from occurring on the window WM.

According to the window WM, the high refractive layer HRL may improve the impact resistance and folding characteristics of the window WM. Since the high refractive layer HRL includes the first base resin, the hardness of the high refractive layer HRL may be lower than the hardness of the low refractive layer LRL, and thus, the high refractive layer HRL may have high impact resistance and folding characteristics. Accordingly, when the display device ED (refer to FIGS. 1B, 1C, and 2B) is folded, defects such as, for example, cracks may be prevented from occurring in the window WM.

The window WM may further include a hard coating layer HC disposed between the base layer BL and the high refractive layer HRL. The hard coating layer HC may protect the base layer BL of the window WM or the display module DM (refer to FIG. 3).

When the window WM further includes the hard coating layer HC, the hard coating layer HC may be disposed directly on the upper surface of the base layer BL. However, the arrangement position of the hard coating layer HC should not be limited to that illustrated in FIG. 5A, and according to an embodiment, the hard coating layer HC may be disposed under the base layer BL in the window WM. According to an embodiment, the window WM may further include an additional hard coating layer (not illustrated) disposed under the base layer BL in addition to the hard coating layer HC disposed on the base layer BL.

The hard coating layer HC may be formed of a hard coating layer resin containing at least one of an organic composition, an inorganic composition, and an organic-inorganic composite composition. As an example, a hard coating agent that forms the hard coating layer may include at least one of an acrylate-based compound, a siloxane-based compound, or a silsesquioxane-based compound. In some aspects, the hard coating agent may further include inorganic particles. The hard coating layer HC may be an organic layer, an inorganic layer, or an organic-inorganic composite material layer.

The hard coating layer HC may have a thickness ranging from about 3 μm to about 10 μm. In an example in which the thickness of the hard coating layer HC is smaller than about 3 μm, the function of protecting the base layer BL may deteriorate, and the durability of the window WM may decrease. In some aspects, in a comparative example in which the thickness of the hard coating layer HC is smaller than about 3 μm, the surface hardness to protect the display module DM (refer to FIG. 3) may not be sufficiently secured. Further, in a comparative example in which the thickness of the hard coating layer HC is greater than about 10 μm, the increased thickness of the window WM may prevent effective implementation of a thin display device or foldable display device. In an example in which the thickness of the hard coating layer HC ranges from about 3 μm to about 10 μm, the hard coating layer HC may have excellent hardness while maintaining the flexibility and may have improved mechanical properties.

The window WM may further include a functional layer AF disposed on the low refractive layer LRL. The functional layer AF may be disposed on the low refractive layer LRL. The functional layer AF may be disposed directly on the low refractive layer LRL. In the case where the window WM further includes the functional layer AF, the functional layer AF may be disposed at an outermost position of the window WM. The functional layer AF may be disposed at an uppermost position of the window WM, and an upper surface of the functional layer AF may be defined as an uppermost surface of the window WM.

The functional layer AF may include a single layer or a plurality of layers. The functional layer AF may include at least one of a hard coating layer, an anti-fingerprint layer, and an anti-scattering layer. The functional layer AF may include a fluorine-containing compound. The functional layer AF including the fluorine-containing compound may be the anti-fingerprint layer.

The functional layer AF may have a thickness ranging from about 10 nm to about 30 nm. In an example in which the thickness of the functional layer AF ranges from about 10 nm to about 30 nm, the functional layer AF may have excellent anti-pollution properties and excellent durability properties.

A display device according to an embodiment may be applied to various electronic devices. An electronic device according to an embodiment may include the foregoing display device, and further include a module or device having other additional function in addition to the display device.

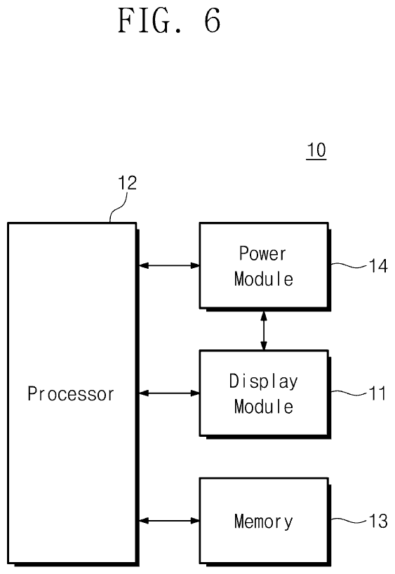

FIG. 6 is a block diagram of an electronic device according to an embodiment. Referring to FIG. 6, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information required for an operation of the processor 12 or the display module 11. When the processor 12 executes an application stored in the memory 13, an image data signal and/or an input control signal may be transmitted to the display module 11, and the display module 11 may process the provided signal and output image information through a display screen.

The power module 14 may include a power supply module such as a power adapter or a battery device, and a power conversion module which converts power supplied by the power supply module and generates power required for an operation of the electronic device 10.

At least one of the components of the electronic device 10 described above may be included in the display device according to an embodiment described above. In addition, some of individual modules included as functional in one module may be included in the display device, and others may be provided separately from the display device. For example, the display device may include the display module 11, and the processor 12, the memory 13, and the power module 14 may be provided not in the display device but in another type of device in the electronic device 10.

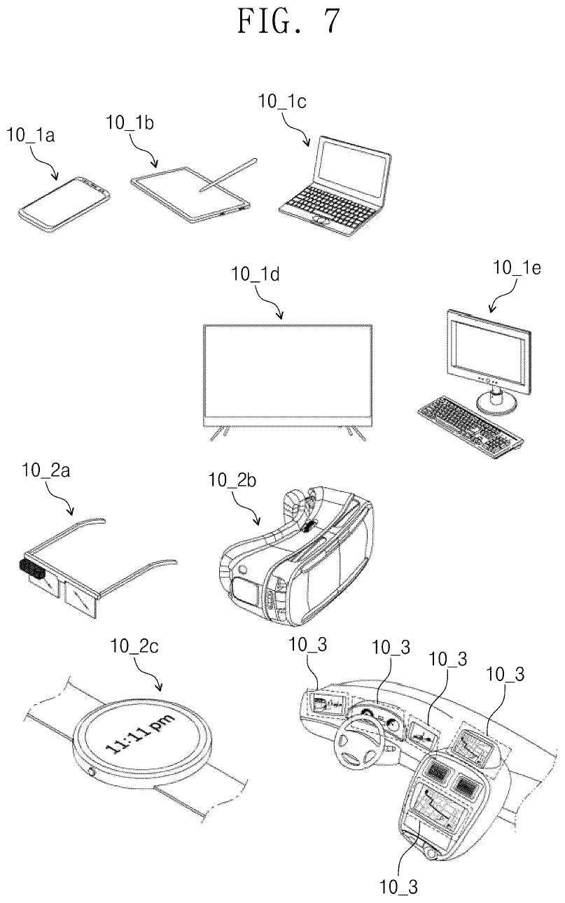

FIG. 7 illustrates schematic views of electronic devices according to various embodiments.

Referring to FIG. 7, various electronic devices to which the display device according to an embodiment is applied may include not only electronic devices for displaying images, e.g., a smartphone 10_1a, a tablet computer (PC) 10_1b, a laptop computer 10_1c, TV 10_1d, and a monitor for a desk computer 10_1e, but also wearable electronic devices including display modules, e.g., smart glasses 10_2a, a head mounted display 10_2b, and a smart watch 10_2c, and vehicle electronic devices 10_3 including display modules, e.g., a vehicle instrument panel, a center fascia, a center information display (CID) disposed on a dashboard, and a room mirror display.

The window WM may have a structure in which the high refractive layer and the low refractive layer are sequentially stacked on the base layer, the high refractive layer may include the base resin, and the low refractive layer may consist of the inorganic particles. Accordingly, anti-reflective properties of the window may be secured while improving abrasion resistance, stretch resistance, and folding characteristics. Accordingly, applying the window WM described herein to the display device may improve mechanical durability of the display device while effectively reducing the amount of reflection of the light incident the display device from the outside, which may thus improve the reliability of the display device.

In some cases, it may be desired for the window of the display device to have the low-reflection characteristics to minimize the reflection of the light incident to the display device from the outside of the display device while exhibiting excellent mechanical properties in protecting the display device from the external impacts. In particular, since the window disposed at the uppermost portion of the display device may be subjected to artificial contact (e.g., impacts) from the outside, it may be desired for the window to have high resistance to external impacts to protect the functional layer disposed at the bottom of the window, such as, for example, the display panel. In some aspects, it may be desired for the window of the flexible display device to protect the display panel without deteriorating folding or bending operations. However, the hardness and the folding characteristics of the window are in a trade-off relationship, and in some cases, simultaneously achieving the hardness and the folding characteristics may be difficult.

Table 1 below illustrates a comparison of physical properties of a film manufactured through the “dry film manufacturing process” and a film manufactured through the “wet film manufacturing process”. In Table 1, a film 1 is the film manufactured by the “dry film manufacturing process” and manufactured by depositing silicon oxide (SiOₓ) with a thickness of about 200 nm on a base layer through a physical deposition process. In some aspects, a film 2 of Table 1 corresponds to the film manufactured by the “wet film manufacturing process”. The film 2 is formed by providing a resin composition, which is obtained by distributing zirconium oxide (ZrOₓ) in an acrylate-based resin, on a base layer and curing the resin composition. The film 2 has a thickness of about 200 nm. The base layer used in the film 1 and the film 2 may correspond to a polyethylene terephthalate (PET) film.

The abrasion resistance, the scratch resistance, and the folding properties of the film 1 and the film 2 are tested to evaluate the physical properties of the film 1 and the film 2.

### (1) Abrasion Resistance

The abrasion resistance may also be referred to as an eraser abrasion resistance. The abrasion resistance was evaluated by applying a load of about 1 kg on the film and repeatedly abrading the film with an eraser, then observing changes in a surface of the film before and after abrasion. The abrasion resistance was evaluated by the changes in contact angle of an upper surface of the film before and after the eraser abrasion test.

### (2) Scratch Resistance

The scratch resistance was evaluated by applying a load of about 1 kg on the film and reciprocating a steel wool (#0000, Liberon Ltd.) on the surface of the film, then visually observing the presence of scratches on the surface. The scratch resistance was evaluated by measuring the number of reciprocating rubs at which one or more scratches of about 1 cm or less were observed with the naked eye.

### (3) Folding Test

The folding test illustrates test results of folding and unfolding operations repeated 200 times. The folding test was performed on both the in-folding and out-folding operations. The folding test was performed at room temperature (25° C.). In the test results of Table 1, “NG” indicates that cracks occurred in the film under the folding test conditions, and “OK” indicates that no cracks occurred in the film under the folding test conditions.

TABLE 1

| | Film 1 | Film 2 |
|---|---|---|
| Abrasion resistance | 10K | 4K |
| Scratch resistance | 3K | 1K |
| Folding test | NG | OK |

Referring to the results of Table 1, in the case of Film 1, it can be seen that there was no change in the surface of Film 1 until the abrasion resistance test was repeated 10,000 times. This means that the abrasion resistance characteristics is improved compared to Film 2 where the change occurred in the surface of Film 2 when the abrasion resistance test was repeated 4000 times in Film 2. In some aspects, in the case of Film 1, it can be seen that there was no change in the surface of Film 1 until the scratch resistance test was repeated 3,000 times. This means that the scratch resistance characteristics is improved compared to Film 2 where the change occurred in the surface of Film 2 when the scratch resistance test was repeated 1000 times in Film 2. In some embodiments, in the case of Film 2, no cracks occurred even after the folding operation is repeated 200 times in the folding test, but in the case of Film 1, cracks occurred after the folding operation is repeated 200 times. That is, Film 2 has improved folding characteristics compared with Film 1. As known from the results of Table 1, when both the high refractive layer and the low refractive layer of the window are manufactured by the “dry film manufacturing process”, the folding characteristics may deteriorate, and cracks may occur during the folding operations. In some aspects, when both the high refractive layer and the low refractive layer of the window are manufactured by the “wet film manufacturing process”, the hardness may decrease, and thus, defects such as, for example, dents, scratches, and the like, caused by external objects may occur in the window. According to the present disclosure, as the high refractive layer HRL of the window WM is manufactured by the “wet film manufacturing process” and the low refractive layer LRL of the window WM is manufactured by the “dry film manufacturing process”, the hardness may increase and the folding characteristics may be improved. The high refractive layer HRL manufactured by the “wet film manufacturing process” may reduce stress generated when the window WM is folded, and thus, the folding characteristics may be improved. The low refractive layer LRL manufactured by the “dry film manufacturing process” may resist local abrasion or compression to maintain high surface hardness.

As described herein, the window WM may include the high refractive layer HRL manufactured by the “wet film manufacturing process” and the low refractive layer LRL manufactured by the “dry film manufacturing process”, and thus, the window WM may have improved anti-reflective properties, high hardness, and excellent folding characteristics. As the window WM may include the base layer BL, the high refractive layer HRL disposed on the base layer BL and including the first base resin BS, and the low refractive layer LRL disposed on the high refractive layer HRL and consisting of the first inorganic particle, the window WM may have excellent optical properties, mechanical durability, and folding characteristics.

FIGS. 5B to 5D are cross-sectional views of the windows. FIGS. 5B to 5D show the windows WM-1, WM-2, and WM-3 different from the window WM illustrated in FIG. 5A. The windows WM-1, WM-2, and WM-3 illustrated in FIGS. 5B to 5D may be the window WM illustrated in FIGS. 3 and 4. The windows WM-1, WM-2, and WM-3 illustrated in FIGS. 5B to 5D may be used as a cover window of the display devices ED and ED-a described with reference to FIGS. 1A to 4.

Descriptions on the layers included in the window WM of FIG. 5A may be equally applied to layers included in the windows WM-1, WM-2, and WM-3 illustrated in FIGS. 5B to 5D. Hereinafter, detailed descriptions of the same elements of the windows WM-1, WM-2, and WM-3 of FIGS. 5B to 5D as those of the window WM (refer to FIG. 5A) will be omitted, and different features from those of the window WM (refer to FIG. 5A) will be described in detail.

The window WM-1 illustrated in FIG. 5B may further include an adhesive layer PM disposed between a high refractive layer HRL and a low refractive layer LRL when compared with the window WM illustrated in FIG. 5A.

The adhesive layer PM may be disposed between the high refractive layer HRL and the low refractive layer LRL. The adhesive layer PM disposed between the high refractive layer HRL and the low refractive layer LRL may increase an adhesive force between the high refractive layer HRL and the low refractive layer LRL. That is, the adhesive layer PM may be an auxiliary layer that increases the adhesive force between the high refractive layer HRL and the low refractive layer LRL. In accordance with embodiments of the present disclosure, a lower surface of the adhesive layer PM may be in contact with an upper surface of the high refractive layer HRL, and an upper surface of the adhesive layer PM may be in contact with a lower surface of the low refractive layer LRL.

The adhesive layer PM may include a silicon-containing compound. The silicon-containing compound included in the adhesive layer PM may be an inorganic compound or an organic compound, which contains silicon. As an example, the adhesive layer PM may include at least one of silicon oxide (SiOₓ), silicon nitride (SiNₓ), silicon oxynitride (SiON), and a silane coupling agent. The silane coupling agent may be a conventional agent known to those skilled in the art.

As the window WM-1 includes the adhesive layer PM, an adhesive strength between the high refractive layer HRL and the low refractive layer LRL may increase. As the adhesive layer PM includes the silicon-containing compound to increase the adhesive force between the high refractive layer HRL and the low refractive layer LRL, a mechanical durability of the window WM-1 may be more improved.

In accordance with embodiments of the present disclosure, the adhesive layer PM may have a thickness ranging from about 10 nm to about 15 nm. In an example in which the thickness of the adhesive layer PM satisfies the above thickness range, the high refractive layer HRL and the low refractive layer LRL may be sufficiently coupled with each other without increasing the overall thickness of the window WM-1.

Referring to FIG. 5C, the window WM-2 may further include a buffer layer BFL disposed adjacent to a low refractive layer LRL. The buffer layer BFL disposed adjacent to the low refractive layer LRL may prevent cracks occurring in the low refractive layer LRL from spreading. As illustrated in FIG. 5C, the buffer layer BFL may serve as an auxiliary layer that prevents the cracks from spreading in the low refractive layer LRL.

When the window WM-2 further includes the buffer layer BFL, the buffer layer BFL may be disposed between a high refractive layer HRL and the low refractive layer LRL. However, the arrangement position of the buffer layer BFL should not be limited to that illustrated in FIG. 5C, and according to an embodiment, the buffer layer BFL of the window WM-2 may be disposed on the low refractive layer LRL. That is, the buffer layer BFL may be disposed between the low refractive layer LRL and a functional layer AF. According to an embodiment, the window WM-2 may further include an additional buffer layer (not illustrated) disposed between the low refractive layer LRL and the functional layer AF in addition to the buffer layer BFL disposed between the high refractive layer HRL and the low refractive layer LRL.

Referring to FIG. 5D, each of a high refractive layer HRL and a low refractive layer LRL of the window WM-3 may be provided in plurality. That is, the window WM-3 may include a plurality of high refractive layers HRL1 and HRL2 and a plurality of low refractive layers LRL1 and LRL2. The high refractive layers HRL1 and HRL2 may alternately arranged with the low refractive layers LRL1 and LRL2 along a thickness direction of the window WM-3.

Each of the high refractive layers HRL1 and HRL2 may have a refractive index greater than the low refractive layers LRL1 and LRL2. The refractive index of each of the high refractive layers HRL1 and HRL2 may range from about 1.7 to about 2.0. As the refractive index of the high refractive layers HRL1 and HRL2 satisfies the refractive index range, a surface reflectance of the window WM-3 may be reduced.

The refractive index of each of the low refractive layers LRL1 and LRL2 may be adjusted in combination with a refractive index of a base layer BL and the high refractive layers HRL1 and HRL2 in association with achieving the reflectance of the entire window WM-3 to be equal to or smaller than about 6%. According to the window WM-3, a surface reflectance of the window WM-3 may be equal to or smaller than about 6% at a wavelength of about 360 nm to about 700 nm. As an example, the surface reflectance of the window WM-3 may be equal to or smaller than about 6% at a wavelength of about 550 nm.

Each of the low refractive layers LRL1 and LRL2 may have the refractive index smaller than the refractive index of the high refractive layers HRL1 and HRL2. The refractive index of each of the low refractive layers LRL1 and LRL2 may range from about 1.2 to about 1.5. However, embodiments of the present disclosure should not be limited thereto or thereby, and the refractive index of the low refractive layer LRL may be adjusted within the range where the window WM-3 maintains the low reflectance characteristics of about 6% or less.

The high refractive layers HRL1 and HRL2 may have thicknesses d_{H1} and d_{H2}, respectively, that range from about 20 nm to about 500 nm. In an example in which each of the high refractive layers HRL1 and HRL2 has the thickness ranging from about 20 nm to about 500 nm, the window WM-3 may have excellent optical properties such as, for example, high transmittance and low reflectance. In some aspects, the window WM-3 including the high refractive layers HRL1 and HRL2 each having the thickness ranging from about 20 nm to about 500 nm may have excellent impact resistance and improved durability.

The low refractive layers LRL1 and LRL2 may have thicknesses d_{L1} and d_{L2}, respectively, that range from about 20 nm to about 100 nm. Preferably, the thicknesses d_{L1} and d_{L2} of the low refractive layers LRL1 and LRL2 may range from about 50 nm to about 100 nm. In an example in which each of the low refractive layers LRL1 and LRL2 has a thickness ranging from about 20 nm to about 100 nm, the window WM-3 may have excellent optical properties such as, for example, high transmittance and low reflectance. In some aspects, the window WM-3 including the low refractive layers LRL1 and LRL2 each having a thickness range from about 20 nm to about 100 nm may have excellent impact resistance and improved durability.

Each of the high refractive layers HRL1 and HRL2 may be alternately stacked with each of the low refractive layers LRL1 and LRL2. That is, the high refractive layers HRL1 and HRL2 and the low refractive layers LRL1 and LRL2 may be stacked such that one of the low refractive layers LRL1 and LRL2 is disposed between the high refractive layers HRL1 and HRL2 and one of the high refractive layers HRL1 and HRL2 is disposed between the low refractive layers LRL1 and LRL2.

As illustrated in FIG. 5D, the window WM-3 may include the base layer BL, a first high refractive layer HRL1 disposed on the base layer BL, a first low refractive layer LRL1 disposed on the first high refractive layer HRL1, a second high refractive layer HRL2 disposed on the first low refractive layer LRL1, and a second low refractive layer LRL2 disposed on the second high refractive layer HRL2. That is, the window WM-3 may include the first high refractive layer HRL1, the first low refractive layer LRL1, the second high refractive layer HRL2, and the second low refractive layer LRL2, which are sequentially disposed on the base layer BL.

Each of the first and second low refractive layers LRL1 and LRL2 may consist of a first inorganic particle. The first inorganic particle included in each of the first and second low refractive layers LRL1 and LRL2 may be low refractive index inorganic oxide. As an example, the first inorganic particle included in each of the first and second low refractive layers LRL1 and LRL2 may be silicon oxide (SiOₓ, 0<x<2). The first inorganic particle included in the first low refractive layer LRL1 may be the same as or different from the first inorganic particle included in the second low refractive layer LRL2.

Each of the first and second high refractive layers HRL1 and HRL2 may include a first base resin BS. The above descriptions on the first base resin BS with reference to FIG. 5A may be equally applied to the first base resin BS of FIG. 5D. The first base resin BS included in the first high refractive layer HRL1 may be the same as or different from the first base resin BS included in the second high refractive layer HRL2. As an example, each of the first base resin BS included in the first high refractive layer HRL1 and the first base resin BS included in the second high refractive layer HRL2 may be a (meta)acrylate-based resin.

Each of the first and second high refractive layers HRL1 and HRL2 may further include a second inorganic particle HP dispersed in the first base resin BS. The second inorganic particle HP included in each of the first and second high refractive layers HRL1 and HRL2 may include high refractive index inorganic oxide. As an example, the second inorganic particle HP may include at least one of zirconium oxide (ZrOₓ), tin oxide (SnOₓ), and titanium oxide (TiOₓ). In some embodiments, x is greater than zero and smaller than two (0<x<2). The second inorganic particle HP included in the first high refractive layer HRL1 may be the same as or different from the second inorganic particle HP included in the second high refractive layer HRL2.

Hereinafter, example aspects of a window (e.g., window WM-1, window WM-2, window WM-3) provided in accordance with one or more embodiments of the present disclosure and a display device including the window will be described in more detail through embodiment examples and a comparative example. However, the following embodiment examples and the comparative example are provided to explain the present disclosure in more detail, and the present disclosure should not be limited by the following embodiment examples and comparative example.

Table 2 illustrates the folding test results of the window of the embodiment examples and the comparative example according to the thickness of the low refractive layer. The embodiment examples and the comparative example illustrated in Table 2 correspond to the window having the stacked structure illustrated in FIG. 5A. That is, embodiment example 1, embodiment example 2, and comparative example 1 correspond to the window including the base layer, the hard coating layer, the high refractive layer, the low refractive layer, and the functional layer, which are sequentially stacked. The difference between the windows of the embodiment examples and the window of the comparative example is the thickness of the low refractive layer, but embodiments of the present disclosure are not limited thereto.

In embodiment example 1, embodiment example 2, and comparative example 1, a polyethylene terephthalate (PET) film was used as the base layer. In embodiment example 1, embodiment example 2, and comparative example 1, the high refractive layer includes an acrylate-based resin as the base resin and zirconium oxide as the inorganic particle. A content of zirconium oxide is about 5 percent by weight based on a total weight of the high refractive layer. In embodiment example 1, embodiment example 2, and comparative example 1, the low refractive layer corresponds to a film formed of silicon oxide (SiOₓ).

The folding characteristics of the windows according to the embodiment examples were evaluated. The folding test illustrates test results of folding and unfolding operations repeated 200 times. The folding test was performed on both the in-folding and out-folding operations. The folding test was performed at room temperature (25° C.). In the test results of Table 2, “NG” indicates that cracks occurred in the window under the folding test conditions, and “OK” indicates that no cracks occurred in the window under the folding test conditions.

TABLE 2

| | Thickness of high | Thickness of | |
|---|---|---|---|
| | refractive layer | low refractive | |
| | (nm) | layer (nm) | Folding test |
| Embodiment | 100 | 50 | OK |
| example 1 | | | |
| Embodiment | 100 | 100 | OK |
| example 2 | | | |
| Comparative | 100 | 200 | NG |
| example 1 | | | |

Referring to Table 2, in the case of embodiment examples 1 and 2, no cracks occurred even after the folding operation is repeated 200 times in the folding test, but in the case of comparative example 1, cracks occurred after the folding operation is repeated 200 times. That is, it is observed that the windows according to embodiment examples 1 and 2 have relatively good folding characteristics compared with the window according to comparative example 1. In the window according to the present disclosure, it is observed that the window has excellent folding characteristics when the thickness of the low refractive layer formed of silicon oxide is about 100 nm or less.

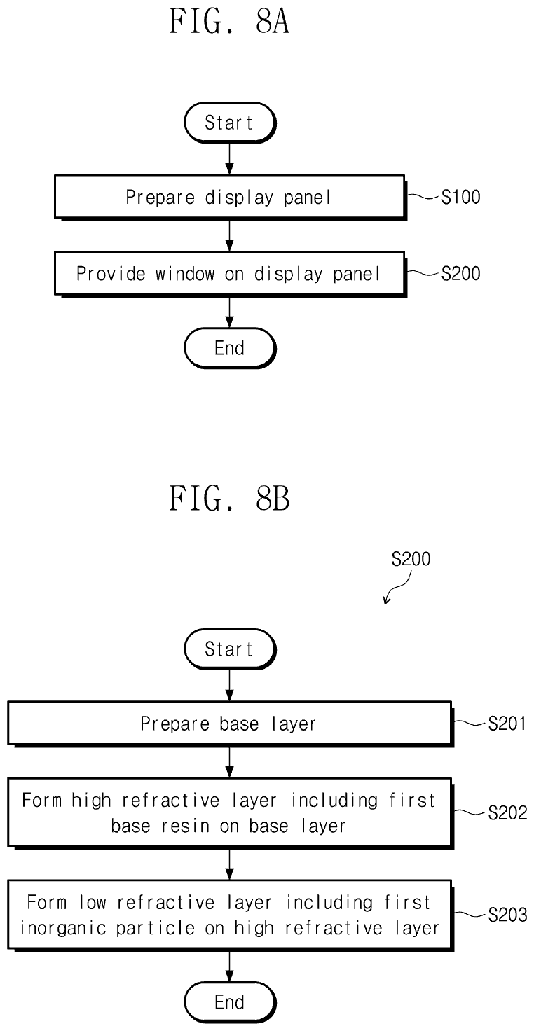

FIG. 8a is a flowchart illustrating a method of manufacturing the display device according to an embodiment of the present disclosure, and FIG. 8b is a flowchart illustrating a process of providing the window according to an embodiment of the present disclosure.

Referring to FIG. 8a, the method of manufacturing the display device includes preparing the display panel (S100) and providing the window on the display panel (S200).

Referring to FIG. 8b, the providing of the window (S200) includes preparing the base layer (S201), forming the high refractive layer including the first base resin on the base layer (S202), and forming the low refractive layer including the first inorganic particle on the high refractive layer (S203). The window WM illustrated in FIGS. 3 and 4 may be formed by the providing of the window described herein.

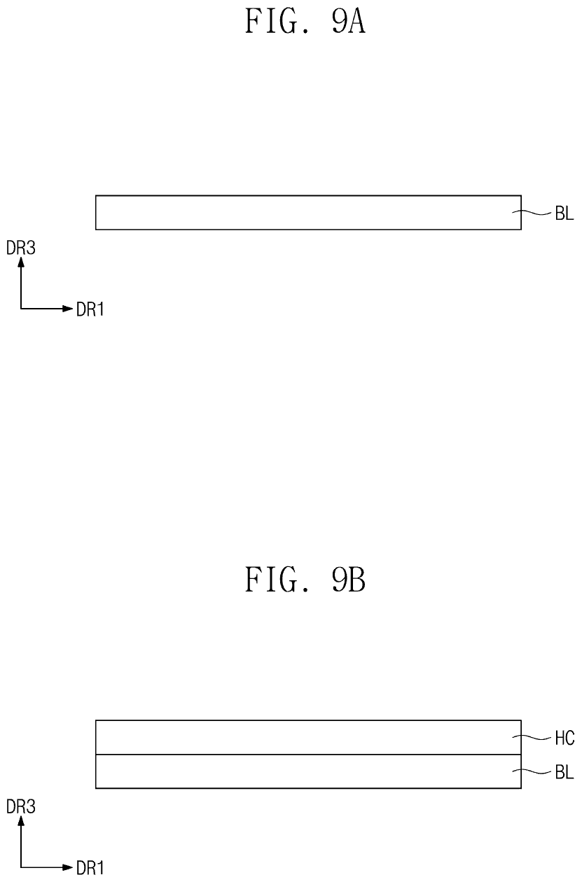

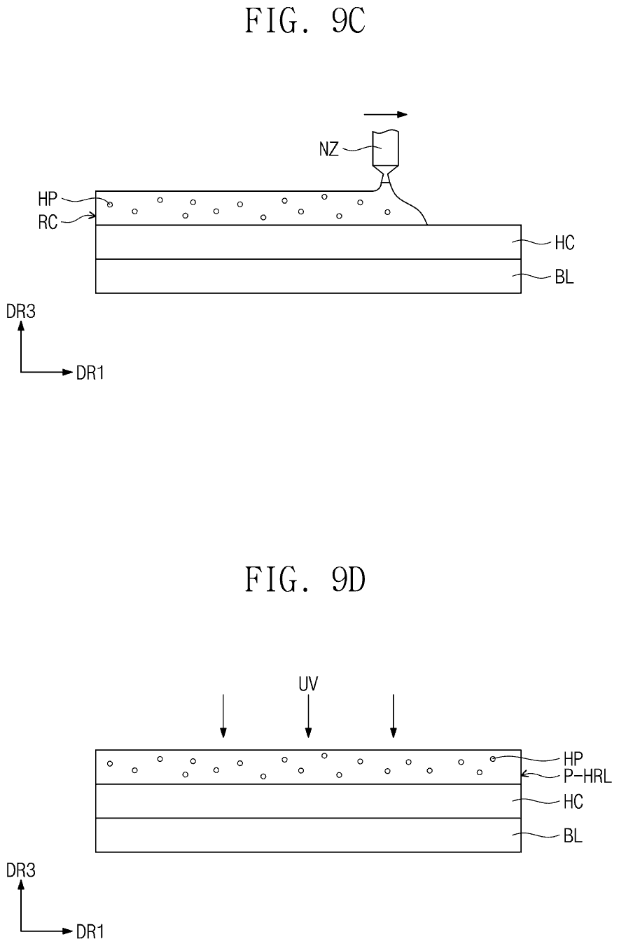

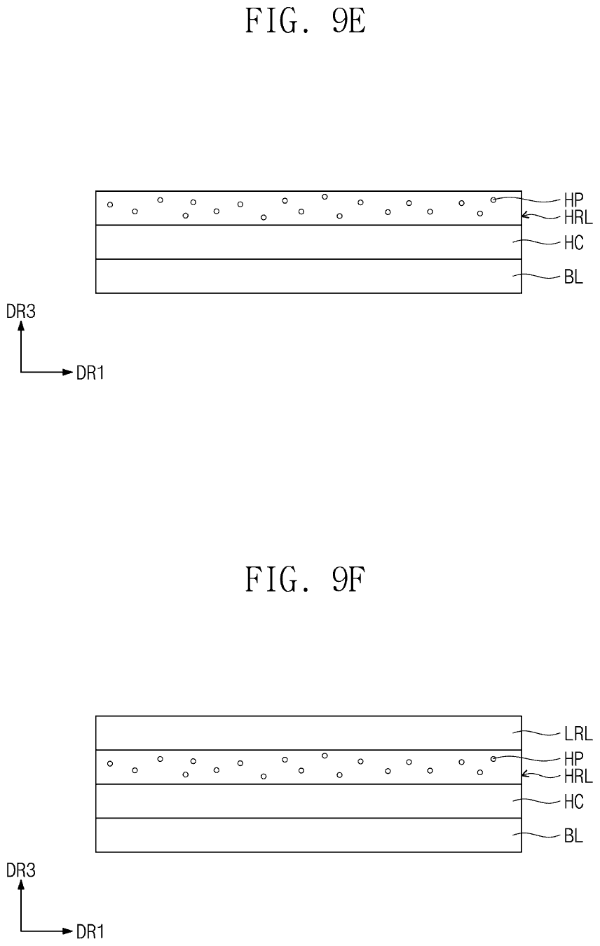

FIGS. 9a to 9f are cross-sectional views illustrating some processes of the method of manufacturing the display device according to an embodiment of the present disclosure. FIGS. 9a to 9f are cross-sectional views illustrating the providing of the window of the method of manufacturing the display device. In accordance with example aspects of the present disclosure, aspects of the window as described herein may be applied to the window of FIGS. 9a to 9f. In FIGS. 9a to 9f, the same reference numerals denote the same elements in FIGS. 1A to 5D, and thus, detailed descriptions of the same elements will be omitted.

The method of manufacturing the display device may include a method of manufacturing the windows WM, WM-1, WM-2, and WM-3 described with reference to FIGS. 5A to 5D. Hereinafter, the method of manufacturing the windows WM, WM-1, WM-2, and WM-3 disposed on the display panel DP (refer to FIG. 4) of the display device ED (refer to FIG. 4) will be described.

The method of manufacturing the display device may include the preparing of the display panel and the providing of the window on the display panel.

FIG. 9a illustrates the preparing of the base layer BL, and FIG. 9b illustrates the forming of the hard coating layer HC on the base layer BL.

Referring to FIGS. 9a and 9b, the method of manufacturing the display device may include the preparing of the base layer BL and the forming of the hard coating layer HC on the base layer BL. In some embodiments, although not illustrated in figures, the method of manufacturing the display device may further include manufacturing the display module DM (refer to FIG. 3) as a part of the display device ED (refer to FIGS. 3 and 4) before the forming of the base layer BL.

The forming of the hard coating layer HC may include providing a hard coating composition on the base layer BL and curing the hard coating composition. The hard coating layer HC may be formed by providing the hard coating composition on the base layer BL and curing the hard coating composition. The coating method for the hard coating composition is not limited to the examples described herein, and embodiments of the present disclosure support including a variety of commonly known coating methods. As an example, various methods, such as, for example, a spin coating method, a dip coating method, a spray coating method, a slit coating method, a roll to roll coating method, or other coating methods may be used, however, embodiments of the present disclosure should not be limited thereto or thereby. Embodiments of the present disclosure may include forming the hard coating layer HC through a curing reaction caused by irradiating the hard coating composition coated on the base layer BL with an ultraviolet ray. However, the present disclosure should not be limited thereto or thereby. According to an embodiment, the forming of the hard coating layer HC may be omitted in the method of manufacturing the display device.

FIG. 9c illustrates the forming of the high refractive layer HRL on the base layer BL. Referring to FIG. 9c, the method of manufacturing the display device may include providing a resin composition RC on the base layer BL to form the high refractive layer HRL. Expressed another way, the method of manufacturing the display device may include coating at least a portion of the base layer BL with the resin composition RC. In an example in which the window includes the hard coating layer HC, the method of manufacturing the display device may include providing the resin composition RC on a surface of the hard coating layer HC. The base layer BL and the hard coating layer HC may serve as a base which may be coated with the resin composition RC that is in a liquid state.

The resin composition RC may include the first base resin. The first base resin included in the resin composition RC may include an acrylic-based resin, a urethane-based resin, a fluorine-based resin, an epoxy-based resin, a polyester-based resin, a polyamide-based resin, a silicone-based resin, or a combination thereof. The first base resin may be provided in a monomer or oligomer form. The method of manufacturing the display device may include providing the first base resin in liquid form before curing the first base resin. In some embodiments, in the present disclosure, the resin composition RC used to form the high refractive layer HRL may be referred to as a first resin composition.

The resin composition RC may further include the second inorganic particle HP. The second inorganic particle HP may include the high refractive index inorganic oxide. As an example, the second inorganic particle HP may include at least one of tin oxide (SnOₓ), titanium oxide (TiOₓ), and zirconium oxide (ZrOₓ).

The resin composition RC may further include additives as applicable or appropriate in support of providing a window (and display device including the window) in accordance with one or more embodiments of the present disclosure. The resin composition RC may further include one or more additives among a filler, a slip agent, an optical stabilizer, a thermal polymerization inhibitor, a leveling agent, a lubricant, an anti-pollution agent, a thickener, a surfactant, an anti-foaming agent, an anti-static agent, a dispersant, an initiators, a coupling agent, an anti-oxidant, a UV stabilizer, and a colorant.

The resin composition RC may be provided by a variety of methods. As an example, the method of manufacturing the display device may include providing the resin composition RC by an inkjet printing method or a dispensing method. The method of manufacturing the display device may include providing the resin composition RC via a supply nozzle NZ, and further, providing the resin composition RC on the base layer BL according to a uniform coating thickness.

FIG. 9d illustrates drying or curing the resin composition RC. Referring to FIGS. 9c and 9d, the method of manufacturing the display device may include performing the drying or curing of a preliminary high refractive layer P-HRL formed by applying the resin composition RC at a uniform thickness (e.g., providing a coating of the resin composition RC at a uniform thickness). As an example, the method of manufacturing the display device may include curing the preliminary high refractive layer P-HRL by providing a light UV to the preliminary high refractive layer P-HRL as illustrated in FIG. 9d. The light UV may be an ultraviolet ray, but embodiments of the present disclosure are not limited thereto.

The light UV used to cure the resin composition RC may be provided to the preliminary high refractive layer P-HRL. The preliminary high refractive layer P-HRL may be polymerized by the light UV provided thereto and cured, thus forming the high refractive layer HRL illustrated in FIG. 9e. The method of manufacturing the display device may include irradiating the preliminary high refractive layer P-HRL with an amount of the light UV which is sufficient to completely cure the resin composition RC, but the amount of light UV used in the method described herein is not limited thereto.

FIG. 9d illustrates the curing of the preliminary high refractive layer P-HRL using the light UV as a representative example. However, the present disclosure should not be limited thereto or thereby. As an example, the method of manufacturing the display device may include applying heat to the preliminary high refractive layer P-HRL to thermally cure the preliminary high refractive layer P-HRL.

FIG. 9f illustrates the forming of the low refractive layer LRL on the high refractive layer HRL. Referring to FIG. 9f, the method of manufacturing the display device may include performing the forming of the low refractive layer LRL including the first inorganic particle on the high refractive layer HRL. The forming of the low refractive layer LRL may be performed by a physical vapor deposition (PVD) process. Embodiments of the present disclosure support varying the specific conditions of the process of forming the low refractive layer LRL based on the type of inorganic material.

The physical vapor deposition process may be performed by an electron beam deposition method or a sputtering method. The physical vapor deposition process to form the low refractive layer LRL may be performed according to commercially available devices and known methods by taking into account the type of the first inorganic particle and the thickness of the low refractive layer. In the physical vapor deposition, a deposition atmosphere, a temperature, a target material, and a vacuum degree may be appropriately selected, and the physical vapor deposition is not particularly limited thereto.

The method of manufacturing the display device may include forming the low refractive layer LRL including the first inorganic particle on the high refractive layer HRL by the physical vapor deposition process. The method of manufacturing the display device may include forming the low refractive layer LRL by depositing the first inorganic particle on the high refractive layer HRL at a uniform thickness by the physical vapor deposition process. The method of manufacturing the display device may include forming the low refractive layer LRL by depositing the first inorganic particle on the high refractive layer HRL at a thickness of about 100 nm or less. The low refractive layer LRL formed by the physical vapor deposition process may consist of the first inorganic particle.

In some embodiments, although not illustrated in figures, the method of manufacturing the display device may further include forming the functional layer AF (refer to FIGS. 5A to 5D) on the low refractive layer LRL after the forming of the low refractive layer LRL.

In some aspects, although not illustrated in figures, the method of manufacturing the display device may further include forming the adhesive layer PM (refer to FIG. 5B) before the forming of the low refractive layer LRL. After the adhesive layer PM (refer to FIG. 5B) including the silicon-containing compound is formed on the high refractive layer HRL, the low refractive layer LRL may be formed on the adhesive layer PM (refer to FIG. 5B).

In some aspects, the method of manufacturing the display device may further include forming the buffer layer BFL before the forming of the low refractive layer LRL. The forming of the buffer layer BFL may include providing a second resin composition including a second base resin (applying a coating of the second resin composition) on the high refractive layer HRL and drying or curing the second resin composition. The second resin composition may include the second base resin and may further include an additive as applicable or appropriate in support of providing a window (and display device including the window) in accordance with one or more embodiments of the present disclosure. The descriptions herein regarding the additive with reference to FIG. 9c may be applied to the additive of the second resin composition. In an example in which the second resin composition coated on the high refractive layer HRL is dried or cured, the method of manufacturing the display device may include forming the low refractive layer LRL on the buffer layer BFL.

In some aspects, the method of manufacturing the display device may include sequentially repeating the forming of the high refractive layer HRL and the forming of the low refractive layer LRL. That is, when the forming of the high refractive layer HRL described with reference to FIGS. 9c to 9e and the forming of the low refractive layer LRL described with reference to FIG. 9f are referred to as a first process, the first process may be performed twice or more in the method of manufacturing the display device.

The window manufactured through the processes illustrated in FIGS. 9a to 9f may be applied to the display device ED. The window manufactured through the processes illustrated in FIGS. 9a to 9f may be provided on the display panel DP (refer to FIG. 4). The window manufactured through the processes illustrated in FIGS. 9a to 9f may be provided on the display panel DP (refer to FIG. 4) after being manufactured through separate processes, however, the present disclosure should not be limited thereto or thereby. According to an embodiment, the window WM may be formed on the display panel DP (refer to FIG. 4) through successive processes.

Although the embodiments of the present disclosure have been described, it is understood that the present disclosure should not be limited to the example embodiments but various changes and modifications can be made by one ordinary skilled in the art within the spirit and scope of the present disclosure as hereinafter claimed. Therefore, the disclosed subject matter should not be limited to any single embodiment described herein, and the scope of some embodiments of the present disclosure may be determined according to the attached claims.

What is claimed is:

1. A display device comprising:
a display panel; and
a window disposed on the display panel, the window comprising:
a base layer disposed on the display panel;
a hard coating layer disposed on the base layer;
a high refractive layer disposed on the hard coating layer and comprising a first base resin; and
a low refractive layer disposed on the high refractive layer and consisting of a first inorganic particle.

2. The display device of claim 1, wherein the high refractive layer has a thickness ranging from about 20 nm to about 100 nm.

3. The display device of claim 1, wherein the high refractive layer further comprises a second inorganic particle distributed in the first base resin.

4. The display device of claim 1, wherein:
the high refractive layer is disposed directly on the hard coating layer, and
the low refractive layer is disposed directly on the high refractive layer.

5. The display device of claim 1, wherein:
the high refractive layer has a refractive index equal to or greater than about 1.7 to about 2.0, and
the low refractive layer has a refractive index equal to or greater than about 1.2 to about 1.5.

6. The display device of claim 1, wherein the first inorganic particle comprises silicon oxide (SiOₓ).

7. The display device of claim 1, wherein the high refractive layer further comprises at least one of tin oxide (SnOₓ), titanium oxide (TiOₓ), and zirconium oxide (ZrOₓ).

8. The display device of claim 1, wherein the first base resin comprises a (meta) acrylate-based resin.

9. The display device of claim 1, wherein the window further comprises a functional layer disposed on the low refractive layer and comprising a fluorine-containing compound.

10. The display device of claim 1, wherein:
each of the high refractive layer and the low refractive layer is provided in plurality, and
the high refractive layers are alternately arranged with the low refractive layers in a thickness direction.

11. The display device of claim 1, wherein the window further comprises an adhesive layer disposed between the high refractive layer and the low refractive layer and comprising a coupling agent.

12. The display device of claim 1, wherein the window further comprises a buffer layer disposed between the high refractive layer and the low refractive layer and comprising a second base resin.

13. The display device of claim 1, further comprising at least one folding area foldable with respect to a folding axis extending in a direction.

14. A display device comprising:
a display panel comprising:
a folding area foldable with respect to a folding axis extending in a direction; and
a non-folding area adjacent to the folding area; and
a window disposed on the display panel, the window comprising;
a base layer disposed on the display panel;
a high refractive layer disposed on the base layer and comprising a first base resin; and
a low refractive layer disposed on the high refractive layer and consisting of a first inorganic particle.

15. The display device of claim 14, wherein the high refractive layer has a thickness equal to or smaller than about 100 nm.

16. A method of manufacturing a display device, comprising:
preparing a display panel; and
providing a window on the display panel, the providing of the window comprising:
preparing a base layer;
forming a high refractive layer comprising a first base resin on the base layer; and
forming a low refractive layer comprising a first inorganic particle on the high refractive layer using a physical deposition, wherein the low refractive layer has a thickness equal to or smaller than about 100 nm.

17. The method of claim 16, wherein the low refractive layer consists of the first inorganic particle.

18. The method of claim 16, wherein the forming of the low refractive layer is performed by an electron beam deposition method or a sputtering method.

19. The method of claim 16, further comprising forming a hard coating layer on a surface of the base layer before the forming of the high refractive layer on the base layer.

20. The method of claim 16, wherein the forming of the high refractive layer comprises:
providing, on the base layer, a resin composition comprising the first base resin and a second inorganic particle distributed in the first base resin; and
drying or curing the resin composition.

21. An electronic device providing an image,
the electronic device comprising:
a display module;
a window disposed on the display panel; and
a housing disposed below the display module and coupled with the window to accommodate the display module,
wherein the window comprising:
a base layer disposed on the display panel;
a hard coating layer disposed on the base layer;
a high refractive layer disposed on the hard coating layer and comprising a first base resin; and
a low refractive layer disposed on the high refractive layer and consisting of a first inorganic particle.
